(19) United States
(12) Patent Application Publication
(10) Pub. No.: US 2024/0251683 A1
(43) Pub. Date: Jul. 25, 2024

(54) TWINNED MICROMACHINED ULTRASONIC TRANSDUCER

(71) Applicant: Infineon Technologies AG, Neubiberg (DE)

(72) Inventors: Mohanraj SOUNDARA PANDIAN, Unterschleißheim (DE); Marten OLDSEN, Tanjung Bungah (MY)

(21) Appl. No.: 18/419,033

(22) Filed: Jan. 22, 2024

(30) Foreign Application Priority Data
Jan. 25, 2023 (DE) 102023200596.4

(51) Int. Cl. H10N 39/00; B06B 1/02; B06B 1/06

(52) U.S. Cl. CPC H10N 39/00; B06B 1/0292; B06B 1/0666

(57) ABSTRACT

Examples disclose an ultrasonic transducer including a set of transducer elements including a capacitive transducer element and a piezoelectric transducer element, wherein the capacitive transducer element and the piezoelectric transducer element are provided laterally separated in a same semiconductor die. Further examples disclose a method of manufacturing an ultrasonic transducer.

### CROSS-REFERENCE TO RELATED APPLICATION

This application claims priority to German Patent Application No. 102023200596.4 filed on Jan. 25, 2023, the content of which is incorporated by reference herein in its entirety.

### TECHNICAL FIELD

The disclosure relates to an ultrasonic transducer and a method for manufacturing an ultrasonic transducer.

### BACKGROUND

Micromachined ultrasonic transducer (MUT) device properties like bandwidth and sensitivity depend on its respective actuation and sensing mechanisms.

US2010/0201222A1 describes ultrasonic transducers, which has been manufactured using a micromachining process. In particular, an ultrasonic transducer is provided in which a capacitive actuated MUT (CMUT) and a piezoelectric actuated MUT (PMUT) are stacked to achieve a synergistic effect to increase the output and the sensitivity of the ultrasonic transducer.

### SUMMARY

There may be a need for providing a further improved ultrasonic transducer.

The need has been addressed with the subject-matter of the independent claims. The dependent claims describe advantageous implementations.

It is proposed an ultrasonic transducer including a set of transducer elements including a capacitive transducer element and a piezoelectric transducer element, wherein the capacitive transducer element and the piezoelectric transducer element are provided laterally separated in a same semiconductor die. Furthermore, a method for manufacturing the ultrasonic transducer is disclosed.

### BRIEF DESCRIPTION OF THE DRAWING

Implementations of the proposed ultrasonic transducer and the proposed method for manufacturing the ultrasonic transducer will now be explained with reference to the enclosed FIGURE.

FIG. 1 shows an ultrasonic transducer.

### DETAILED DESCRIPTION

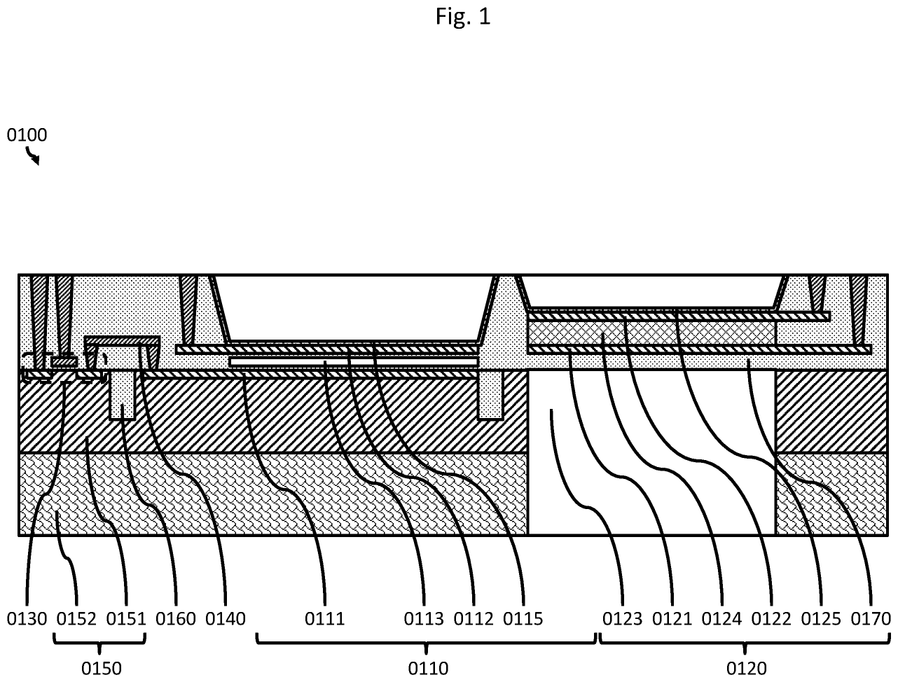

FIG. 1 illustrates an ultrasonic transducer 0100 comprising a set of transducer elements including a capacitive transducer element 0110 and a piezoelectric transducer element. The capacitive transducer element 0110 and the piezoelectric transducer element 0120 are provided laterally separated in a same semiconductor die. Providing the capacitive transducer element 0110 and the piezoelectric transducer element 0120 laterally separated in a same semiconductor die may, on the one hand, reduce the mutual influence of the acoustic properties of the capacitive transducer element 0110 and, on the other hand, allow to benefit from the high bandwidth of a CMUT and the high transmitting sensitivity of a PMUT.

The ultrasonic transducer 0100 may further comprise an active semiconductor component 0130, in particular a transistor. The active semiconductor component 0130 may be part of an ASIC. The ASIC may be used for controlling the capacitive transducer element 0110 and/or the piezoelectric transducer element 0120.

An interlayer connector 0140 may electrically connect the active semiconductor component 0130 to at least one of the bottom capacitive transducer element electrode 0111, the top capacitive transducer element electrode 0112, the bottom piezoelectric transducer element electrode 0121 and the top piezoelectric transducer element electrode 0122.

The capacitive transducer element 0110 may comprise a hermitically sealed cavity 0113. In some examples, a pressure in the cavity 0113 may be approximately 1013 mbar. The pressure in the cavity may correspond to atmospheric pressure. In some implementations, the pressure in the cavity 0113 may be below 100 mbar, in particular below 10 mbar.

The piezoelectric transducer element 0120 may also include a cavity 0123. In contrast to the cavity 0113 of the capacitive transducer element 0110, the cavity 0123 of the piezoelectric transducer element 0120 is an open cavity. In particular, the cavity 0123 may have been formed by etching from a backside of the substrate 0150. However, in some examples, the cavity of the piezoelectric transducer element 0120 may also be a hermetically sealed cavity as has been described with respect to the capacitive transducer element 0110.

The substrate 0150 may comprise a semiconductor layer 0151 on top of a dielectric layer 0152. The substrate 0150 may correspond to a wafer. In particular, the substrate 0150 may correspond to an SOI (silicon on insulator) wafer.

The bottom capacitive transducer element electrode 0111 may be made from a doped semiconductor material, in particular from doped silicon. In some examples, the bottom capacitive transducer element electrode 0111 may be made from an implanted semiconductor layer, for example from the semiconductor layer 0151. A dopant of the doped semiconductor material may comprise at least one of Ar and P.

Portions, in particular doped portions, of the semiconductor layer 0151 may be insulated from each other using shallow trench insulation (STI) 0160.

The top capacitive transducer element electrode 0112 may be provided in a same layer as the bottom piezoelectric transducer element electrode 0121. For example, the top capacitive transducer element electrode 0112 and the bottom piezoelectric transducer element electrode 0121 may be structured from a common or doped semiconductor material or metal layer. In some examples, the top capacitive transducer element electrode 0112 and the bottom piezoelectric transducer element electrode 0121 may be made from doped polysilicon.

The piezoelectric transducer element 0120 may comprise a piezoelectric layer 0124 made from at least one of AlN, AlScN and PZT. The piezoelectric layer may be deposited using at least one of PVD, ALD and PLD.

The top piezoelectric transducer element electrode 0122 may be made from a metal, in particular from at least one of Al, Au, Cu.

At least one of the capacitive transducer element 0110 and the piezoelectric transducer element 0120 may comprise a frequency tuning layer 0115, 0125. The frequency tuning layer 0115, 0125 may be made from at least one of SiO₂, SiN, SiOₓN. The frequency tuning layer 0115, 0125 may be used to fine tune the transmission and/or reception properties of the capacitive transducer element 0110 and the piezoelectric transducer element 0120, respectively. A thickness of the frequency tuning layer 0115 may be the same or different from a thickness of the frequency tuning layer 0125. The difference in thickness may be used to adapt the frequency properties of the capacitive transducer element 0110 and the piezoelectric transducer element 0120 to each other.

The capacitive transducer element 0110, the piezoelectric transducer element 0120, the interlayer connector 140 and/or the active semiconductor component 0130 may be embedded in an embedding layer 0170. The embedding layer 0170 may be an insulating layer. The layer 0170 may be used as an etch stop layer when etching the cavity 0123.

FIG. 1 shows only a single set of two transducer elements. However, several sets of transducer elements may be combined to form an array of sets of transducer elements. In addition, each set of transducer elements may comprise more than one capacitive transducer element and/or more than one piezoelectric transducer element.

### Aspects

In particular, the following Aspects are disclosed:

ASPECT 1. An ultrasonic transducer (0100) comprising a set of transducer elements including a capacitive transducer element (0110) and a piezoelectric transducer element (0120), wherein the capacitive transducer element (0110) and the piezoelectric transducer element (0120) are provided laterally separated in a same semiconductor die.

ASPECT 2. The ultrasonic transducer (0100) of ASPECT 1, wherein the capacitive transducer element (0110) comprises a bottom capacitive transducer element electrode (0111) and a top capacitive transducer element electrode (0112), wherein the piezoelectric transducer element (0120) comprises a bottom piezoelectric transducer element electrode (0121) and a top piezoelectric transducer element electrode (0122), wherein the top capacitive transducer element electrode (0112) is provided in a same layer as the bottom piezoelectric transducer element electrode (0121).

ASPECT 3. The ultrasonic transducer (0100) of ASPECT 1 or 2, wherein the capacitive transducer element (0110) and/or the piezoelectric transducer element (0120) comprises a cavity (0113; 0123), in particular a hermetically sealed cavity (0113).

ASPECT 4. The ultrasonic transducer (0100) of ASPECT 3, wherein a pressure in the cavity (0113) is approximately 1013 mbar.

ASPECT 5. The ultrasonic transducer (0100) of ASPECT 3 or 4, wherein a pressure in the cavity (0113) is below 100 mbar, in particular below 10 mbar.

ASPECT 6. The ultrasonic transducer (0100) of any one of Aspects 2 to 5, wherein the bottom capacitive transducer element electrode (0111) is made from a doped semiconductor material, in particular from doped silicon.

ASPECT 7. The ultrasonic transducer (0100) of ASPECT 6, wherein the bottom capacitive transducer element electrode (0111) is made from an implanted semiconductor layer.

ASPECT 8. The ultrasonic transducer (0100) of ASPECT 6 or 7, wherein a dopant of the doped semiconductor material comprises at least one of Ar and P.

ASPECT 9. The ultrasonic transducer (0100) of any one of Aspects 2 to 8, wherein the top capacitive transducer element electrode (0112) and the bottom piezoelectric transducer element electrode (0121) are made from a doped semiconductor material or a metal.

ASPECT 10. The ultrasonic transducer (0100) of ASPECT 9, wherein the top capacitive transducer element electrode (0112) and the bottom piezoelectric transducer element electrode (0121) are made from doped polysilicon.

ASPECT 11. The ultrasonic transducer (0100) of any one of Aspects 2 to 10, wherein the top piezoelectric transducer element electrode (0122) is made from a metal, in particular from at least one of Al, Au, Cu.

ASPECT 12. The ultrasonic transducer (0100) of any one of Aspects 1 to 11, wherein the piezoelectric transducer element (0120) comprises a piezoelectric layer (0124) made from at least one of AlN, AlScN, PZT.

ASPECT 13. The ultrasonic transducer (0100) of any one of Aspects 1 to 12, wherein at least one of the capacitive transducer element (0110) and the piezoelectric transducer element (0120) comprises a frequency tuning layer (0115; 0125).

ASPECT 14. The ultrasonic transducer (0100) of any one of Aspects 1 to 13, wherein the frequency tuning layer (0115, 0125) is made from at least one of SiO₂, SiN, SiOₓN.

ASPECT 15. The ultrasonic transducer (0100) of any one of Aspects 1 to 14, wherein the semiconductor die comprises an active semiconductor component (0130), in particular a transistor.

ASPECT 16. The ultrasonic transducer (0100) of any one of Aspects 1 to 15, wherein an interlayer connector (0140) electrically connects the active semiconductor component (0130) to at least one of: the bottom capacitive transducer element electrode (0111), the top capacitive transducer element electrode (0112), the bottom piezoelectric transducer element electrode (0121), the top piezoelectric transducer element electrode (0122).

ASPECT 17. The ultrasonic transducer (0100) of ASPECT 16, wherein the semiconductor die comprises an ASIC, wherein the ASIC comprises the active semiconductor component (0130).

ASPECT 18. The ultrasonic transducer (0100) of any one of Aspects 1 to 17, wherein the semiconductor die comprises an array of sets of transducer elements including the set of transducer elements.

ASPECT 19. A method of manufacturing an ultrasonic transducer element (0100) of any one of Aspects 1 to 18.

ASPECT 20. The method of manufacturing an ultrasonic transducer element (0100) of ASPECT 19, further comprising—depositing a piezoelectric layer (0124) using at least one of PVD, ALD and PLD.

ASPECT 21. The method of manufacturing an ultrasonic transducer element (0100) of ASPECT 19 or 20, further comprising depositing the top piezoelectric transducer element electrode (0122) using at least one of PVD or plating.

ASPECT 22. The method of manufacturing an ultrasonic transducer element (0100) of any one of Aspects 19 to 21, further comprising etching a cavity (0123) from a backside of a substrate (0150).

While several implementations have been described with reference to the drawing, this description is not intended to be construed in a limited sense. Various modifications and combinations of the illustrative implementations, as well as other implementations, will be apparent to persons skilled in the art upon reference to the description. It is therefore intended that the appended claims encompass any such modifications or implementations.

1. An ultrasonic transducer comprising:
a set of transducer elements including:
a capacitive transducer element; and
a piezoelectric transducer element,
wherein the capacitive transducer element and the piezoelectric transducer element are provided laterally separated in a same semiconductor die.

2. The ultrasonic transducer of claim 1, wherein the capacitive transducer element comprises a bottom capacitive transducer element electrode and a top capacitive transducer element electrode,
wherein the piezoelectric transducer element comprises a bottom piezoelectric transducer element electrode and a top piezoelectric transducer element electrode, and
wherein the top capacitive transducer element electrode is provided in a same layer as the bottom piezoelectric transducer element electrode.

3. The ultrasonic transducer of claim 1, wherein at least one of the capacitive transducer element or the piezoelectric transducer element comprises a hermetically sealed cavity.

4. The ultrasonic transducer of claim 3, wherein a pressure in the hermetically sealed cavity is approximately 1013 mbar.

5. The ultrasonic transducer of claim 3, wherein a pressure in the hermetically sealed cavity is below 10 mbar.

6. The ultrasonic transducer of claim 2, wherein the bottom capacitive transducer element electrode is made from a doped semiconductor material.

7. The ultrasonic transducer of claim 6, wherein the bottom capacitive transducer element electrode is made from an implanted semiconductor layer.

8. The ultrasonic transducer of claim 6, wherein a dopant of the doped semiconductor material comprises at least one of Ar or P.

9. The ultrasonic transducer of claim 2, wherein the top capacitive transducer element electrode and the bottom piezoelectric transducer element electrode are made from a doped semiconductor material or a metal.

10. The ultrasonic transducer of claim 9, wherein the top capacitive transducer element electrode and the bottom piezoelectric transducer element electrode are made from doped polysilicon.

11. The ultrasonic transducer of claim 2, wherein the top piezoelectric transducer element electrode is made from a metal.

12. The ultrasonic transducer of claim 1, wherein the piezoelectric transducer element comprises a piezoelectric layer made from at least one of AlN, AlScN, or PZT.

13. The ultrasonic transducer of claim 1, wherein at least one of the capacitive transducer element and the piezoelectric transducer element comprises a frequency tuning layer.

14. The ultrasonic transducer of claim 13, wherein the frequency tuning layer is made from at least one of SiO₂, SiN, or SiOₓN.

15. The ultrasonic transducer of claim 2, wherein the semiconductor die comprises an active semiconductor component.

16. The ultrasonic transducer of claim 15, wherein an interlayer connector electrically connects the active semiconductor component to at least one of:
the bottom capacitive transducer element electrode,
the top capacitive transducer element electrode,
the bottom piezoelectric transducer element electrode,
the top piezoelectric transducer element electrode.

17. The ultrasonic transducer of claim 16, wherein the semiconductor die comprises an ASIC, wherein the ASIC comprises the active semiconductor component.

18. The ultrasonic transducer of claim 1, wherein the semiconductor die comprises an array of sets of transducer elements including the set of transducer elements.

19. (canceled)

20. A method of manufacturing an ultrasonic transducer element comprising a set of transducer elements, wherein the set of transducer elements includes a capacitive transducer element and a piezoelectric transducer element, the method comprising:
providing the capacitive transducer element and the piezoelectric transducer element laterally separated in a same semiconductor die;
depositing a piezoelectric layer using at least one of PVD, ALD and PLD; and
depositing a top piezoelectric transducer element electrode using at least one of PVD or plating.

21. (canceled)

22. The method of manufacturing an ultrasonic transducer element of claim 20, further comprising
etching a cavity from a backside of a substrate.
